(19) United States
(12) Patent Application Publication
(10) Pub. No.: US 2016/0308081 A1
(43) Pub. Date: Oct. 20, 2016

(54) SOLAR CELL MODULE

(71) Applicant: Panasonic Intellectual Property Management Co., Ltd., Osaka (JP)

(72) Inventors: Tasuku Ishiguro, Osaka (JP); Shihomi Nakatani, Osaka (JP)

(73) Assignee: Panasonic Intellectual Property Management Co., Lt d., Osaka (JP)

(21) Appl. No.: 15/091,328

(22) Filed: Apr. 5, 2016

Related U.S. Application Data
(63) Continuation of application No. PCT/JP2014/004663, filed on Sep. 10, 2014.

(30) Foreign Application Priority Data
Oct. 16, 2013 (JP) 2013-215345

(51) Int. Cl. H01L 31/048; H01L 31/049; H01L 31/052; H01L 31/02

(52) U.S. Cl. CPC H01L 31/0481; H01L 31/02013; H01L 31/0201; H01L 31/049; H01L 31/052; H02S 40/34

(57) ABSTRACT

A solar cell module is provided with: a first encapsulant that is provided between a plurality of solar cells and a first protective member; a second encapsulant that comprises a different material to that of the first encapsulant and that is provided between the solar cells and a second protective member; and a third encapsulant that comprises the same material as the first encapsulant and that is provided between the solar cells and a output wiring member.

### TECHNICAL FIELD

The present invention generally relates to a solar cell module.

### BACKGROUND ART

A solar cell module typically includes a structure in which a solar cell string formed of a plurality of solar cells connected through conductive wires is sandwiched between two protective members, and a space between the solar cell string and each of the protective members is filled with a encapsulant (for example, see Patent Literature 1). As the protective member, for example, a glass substrate may be used on a light-receiving surface side that receives sunlight mainly, and a resin sheet may be used on rear surface side. Patent Literature 1 discloses that resins different in composition from each other are used for a encapsulant in contact with the glass substrate on the light-receiving surface side and for a encapsulant in contact with the resin sheet on the rear surface side in order to achieve both weather resistance and heat resistance.

The solar cell module includes an output wiring member that is drawn to the rear surface side of the module to be coupled to a terminal unit in order to extract electric power from the solar cells. The solar cell module may be manufactured by, for example, laminating a solar cell string attached with the output wiring member with use of protective members and a sheet encapsulant. In this case, in addition to two sheet encapsulants in contact with respective protective members, a third encapsulant is provided between the solar cells and the output wiring member.

### CITATION LIST

### Patent Literature

Patent Literature 1: Japanese Patent Laid-Open Publication No. 2011-159711

### SUMMARY OF INVENTION

### Technical Problem

Incidentally, the terminal unit connected with the output wiring member easily becomes high in temperature during electric power generation of the solar cells, and temperature difference between when the electric power generation is in progress and when electric power generation is not in progress becomes large in the vicinity of the terminal unit compared with other sections. Such large temperature variation may adversely affect output characteristics of the solar cell module.

### Solution to Problem

The inventers found, as a result of diligent study to solve the above-described disadvantage, that using, as a third encapsulant, a encapsulant formed of the same material as that of the encapsulant provided on the light-receiving surface side of the solar cells improves the output characteristics of the solar cell module. As a result, the inventers have achieved the present invention.

A solar cell module according to the present invention is provided with: a plurality of solar cells; a first protective member that is provided on a light-receiving surface side of the solar cells; a second protective member that is provided on a rear surface side of the solar cells; an output wiring member that passes through the rear surface side of the solar cells and is drawn to the rear surface side of the second protective member; a terminal unit that is provided on the rear surface side of the second protective member and to which the output wiring member is connected; a first encapsulant that is provided between the solar cells and the first protective member; a second encapsulant that is formed of a different material than the first encapsulant and is provided between the solar cells and the second protective member; and a third encapsulant that is formed of the same material as the first encapsulant and is provided between the solar cells and the output wiring member.

### Advantageous Effect of Invention

According to the present invention, the solar cell module improved in output characteristics may be provided.

### BRIEF DESCRIPTION OF DRAWINGS

FIG. 1 is a diagram of a solar cell module as an example embodiment of the present invention as viewed from light-receiving surface side.

FIG. 2 is a diagram illustrating a part of a sectional surface taken along a line AA in FIG. 1.

FIG. 3 is a diagram for explaining a method of manufacturing the solar cell module as the example embodiment of the present invention.

### DESCRIPTION OF EMBODIMENTS

Some embodiments of the present invention are described in detail below with reference to drawings.

The drawings referred in the embodiments are merely illustrated schematically, and a dimension ratios, etc., of components drawn in the drawings may be different from actual dimension ratios, etc. Specific dimension ratios, etc. should be determined by taking into consideration of the following description.

A “light-receiving surface” of a solar cell module and solar cells used herein refers to a surface mainly receiving sunlight (with a percentage of higher than 50% to 100%), and a “rear surface” used herein refers to a surface on a side opposite to the light-receiving surface. The terms of the light-receiving surface and the rear surface are used for other components such as a protective member. Also, description of “providing a second member on a first member”, etc. is not intended to limit to a case where the first and second members are provided in directly contact with each other. In other words, this description includes a case where any other member exists between the first member and the second member.

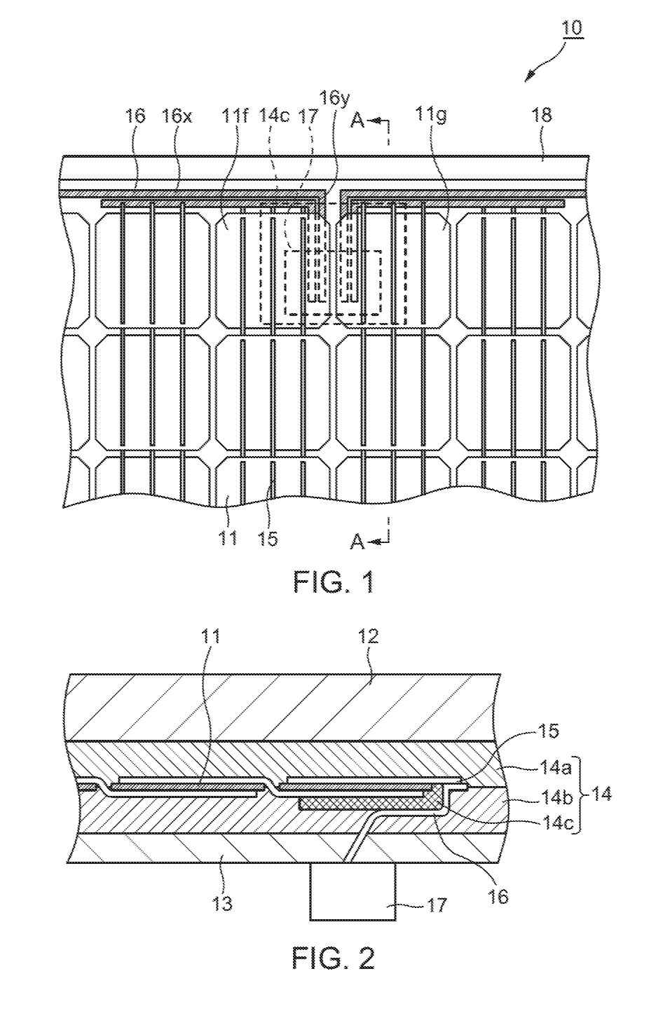

As illustrated in FIGS. 1 and 2, a solar cell module 10 includes: a plurality of solar cells 11; a first protective member 12 provided on the light-receiving surface side of the solar cells 11; and a second protective member 13 provided on the rear surface side of the solar cells 11. The plurality of solar cells 11 are sandwiched between the first protective member 12 and the second protective member 13, and are sealed by a encapsulant 14 that is filled in a space between the solar cells 11 and each of the protective members. A layer of the encapsulant 14 is configured of three encapsulants as described in detail later.

In the present embodiment, the solar cells 11 adjacent to each other are connected to each other through a conductive wire 15 to form a plurality of (for example, six) strings. Each of the strings is configured of the plurality of solar cells 11 that are arranged in line and connected in series to one another through the conductive wire 15. The solar cell module 10 includes a wiring material connected with the conductive wire 15 that is extended from an edge of the solar cells 11 provided at an end of the string (an end of the line of the solar cells 11).

The solar cell module 10 includes, as the above-described wiring material, an output wiring member 16 to extract electrical power from the solar cells 11. The output wiring member 16 passes through the rear surface side of the solar cells 11 and is drawn to the rear surface side of the second protective member 13. Note that the output wiring member 16 may be configured of a plurality of materials coupled to one another or may be configured of one material. As the wiring material, a connection wiring material (not illustrated) that simply connects the strings is provided, in addition to the output wiring member 16.

In the present embodiment, a total of four output wiring members 16 serving as two positive terminals and two negative terminals are provided. Each of the output wiring members 16 extends substantially orthogonal to a longitudinal direction of the conductive wire 15 (the string), and includes a first part 16x and a second part 16y. The first part 16x is connected with each of the conductive wires 15, and the second part 16y extends substantially parallel to the longitudinal direction of the conductive wires 15. The second part 16y of each of the output wiring members 16 passes through just the rear side of solar cells 11f and 11g that are located at respective ends of two central strings. A front end thereof is drawn to a terminal box 17 that is described later.

The solar cell module 10 includes a terminal unit provided on the rear surface side of the second protective member 13. The terminal unit may preferably include a terminal block (not illustrated) and the terminal box 17. The terminal block is connected with the output wiring members 16 and an electric power cable connected with an external apparatus, and the terminal box 17 houses the terminal block. The terminal box 17 may preferably include a bypass diode that contributes to stabilization of the output, in addition to the terminal block. In the present embodiment, the terminal box 17 is attached at a position overlapped, in the thickness direction of the solar cell module 10, with the solar cells 11f and 11g. The terminal box 17 may be preferably attached at the position where the output wiring members 16 are drawn.

The solar cell module 10 may preferably include a frame 18 that is attached with a periphery of the first protective member 12 and the second protective member 13. The frame 18 protects the periphery of the protective members and is used to dispose the module on a roof or the like.

The solar cells 11 each include a photoelectric conversion section that receives sunlight to generate carriers. The photoelectric conversion section may include a light-receiving surface electrode formed on the light-receiving surface thereof, and a rear surface electrode formed on the rear surface thereof (both not illustrated). The rear surface electrode may be preferably formed to have an area larger than that of the light-receiving surface electrode. The structure of each solar cell 11 is not particularly limited, and may be a structure in which, for example, an electrode is provided only on the rear surface of the photoelectric conversion section. Note that a surface larger in electrode area or a surface provided with the electrode is regarded as the “rear surface”.

The photoelectric conversion section includes a semiconductor substrate of, for example, crystalline silicon (c-Si), gallium arsenide (GaAs) or an indium phosphide (InP), an amorphous semiconductor layer formed on the semiconductor substrate, and a transparent conductive layer formed on the amorphous semiconductor layer. Specific examples of the photoelectric conversion section may include a structure in which an i-type amorphous silicon, layer, a p-type amorphous silicon layer, and a transparent conductive layer are provided in order on the light-receiving surface of an n-type monocrystal silicon substrate, and an i-type amorphous silicon layer, an n-type amorphous silicon layer, and a transparent conductive layer are provided in order on the rear surface thereof. The transparent conductive layer may be preferably formed of a transparent conductive oxide that is metal oxide such as indium oxide (In₂O₃) and zinc oxide (ZnO) doped with tin (Sn), antimony (Sb), or the like.

The electrode may include, for example, a plurality of finger sections and a plurality of bus bar sections. The finger sections are each a thin wire electrode provided in a wide region on the transparent conductive layer. The bus bar sections are each an electrode collecting carriers from the finger sections. In the present embodiment, three bus bar sections are provided on each surface of the photoelectric conversion section, and the conductive wire 15 is attached on each of the bus bar sections. The conductive wire 15 is an elongated member formed of a metal such as aluminum, and connects the adjacent, solar cells 11 to each other in series to form the string. The conductive wire 15 is bent in the thickness direction of the solar cell module 10 between the adjacent solar cells 11, and is attached to the light-receiving surface of one of the solar cells 11 and to the rear surface of the other solar cell 11 with use of an adhesive or the like.

A transparent member such as a glass substrate, a resin substrate, and a resin film may be used for the first protective member 12. Among them, the glass substrate may be preferably used in terms of fire resistance, durability, and the like. The thickness of the glass substrate is not particularly limited, however, and may preferably be about 2 mm to about 6 mm, both inclusive.

The transparent member that is the same as that of the first protective member 12 or an opaque member may be used for the second protective member 13. In the present embodiment, a resin film is used as the second protective member 13. The resin film is not particularly limited, but may preferably be a polyethylene terephthalate (PET) film. In terms of lowering moisture permeability, the resin film may include a metal layer formed of aluminum or the like, and an inorganic compound layer formed of silica or the like. A thickness of the resin film is not particularly limited, but may preferably be about 100 μm to about 300 μm, both inclusive.

The encapsulant 14 is used to seal the solar cells 11. A constituent material of the encapsulant 14 contains a resin applicable to a laminating process described later as a main component, (exceeding 50% by weight), preferably contains 80% by weight or more of the resin, and more preferably contains 90% by weight, or more of the resin. The encapsulant 14 may contain various kinds of additives such as an antioxidant, a flame retardant, and a encapsulant 14b, described later, and may contain various kinds of additives such as a pigment formed of titanium oxide, or the like.

Examples of the resin suitable as a main component of the encapsulant 14 may include an olefin-based resin obtained by polymerizing at least one kind selected from 2 to 20 C α-olefins (for example, polyethylene, polypropylene, or random or block copolymer of ethylene with other α-olefin), an ester-based resin (for example, polycondensate of polyol and polycarboxilic acid or acid anhydride or lower alkyl ester thereof), an urethane-based resin (for example, a polyaddition product of polyisocyanate and an active hydrogen group-containing compound (such as diol, polyol, dicarboxylic acid, polycarboxylic acid, polyamine, and polythiol)), an epoxy-based resin (for example, a ring-opened polymerized product of polyepoxide, and a polyaddition product of polyepoxide and the above-described active hydrogen group-containing compound), and a copolymer of α-olefin and vinyl carboxylate, acrylic ester, or other vinyl monomer.

Among them, an olefin-based resin (in particular, an ethylene-containing polymer) and a copolymer of α-olefin and vinyl carboxylate may be particularly preferable. As the copolymer of α-olefin and vinyl carboxylate, ethylene-vinyl acetate copolymer (EVA) may be particularly preferable.

The encapsulant 14 includes the first encapsulant 14a provided between the solar cells 11 and the first protective member 12 (hereinafter, simply referred to as the “encapsulant 14a”), the second encapsulant 14b provided between the solar cells 11 and the second protective member 13 (hereinafter, simply referred to as the “encapsulant 14b”), and a third encapsulant 14c provided between each of the solar cells 11 and each of the output wiring members 16 (hereinafter, simply referred to as the “encapsulant 14c”). In other words, the encapsulant 14a is disposed on the light-receiving surface side of the solar cells 11, and the encapsulants 14b and 14c are disposed on the rear surface side of the solar cells 11. A thickness of each of the encapsulants 14a and 14b is not particularly limited, but may preferably be about 100 μm to about 600 μm, both inclusive.

The encapsulants 14a and 14b are formed of materials that are different from each other in order to achieve both temperature-cycle resistance and high-temperature and high-humidity resistance. For example, the encapsulants 14a and 14b may be the same in resin composition of the main component, and may be different in amount of the main component, a kind of the above-described additives, or the like from each other, but may preferably contain respective resins different in composition from each other. The constituent materials suitable for the encapsulants 14a and 14b and the combination thereof depend on the structure and purpose (usage environment) of the solar cell module 10. Typically, a resin high in crosslinking density may be preferably used for the encapsulant 14a, and a resin low in crosslinking density may be preferably used for the encapsulant 14b. In other words, the resin forming the encapsulant 14a (hereinafter, referred to as a “resin 14a”) may preferably have crosslinking density higher than that of the resin forming the encapsulant 14b (hereinafter, referred to as a “resin 14b”). Note that the crosslinking density of the resin is evaluated by gel fraction.

The gel fraction is measured by the following method.

1 g of resin to be measured is prepared, and is immersed in 100 ml of xylene at 120° C. for 24 hours. Thereafter, residues in xylene are extracted, and then dried at 80° C. for 16 hours. The mass of the dried residues is measured. Then, the gel fraction (%) is calculated based on the expression (1).

gel fraction (%)=(mass of residues)/(mass of resin before immersion) Expression (1):

The gel fraction of the resin becomes higher as the crosslinking density of the resin becomes high, and becomes lower as the crosslinking density of the resin becomes low.

The gel fraction of the resin 14a may be preferably about 50% to about 90%, both inclusive, and more preferably about 55% to about 80%, both inclusive. The gel fraction of the resin 14b is lower than that of the resin 14a, and may be preferably 40% or lower. The resin 14b may be a non-crosslinkable resin (having substantially 0% of gel fraction). The crosslinking density of the resin may be adjusted by, for example, changing a kind and an addition amount of a crosslinking agent forming a crosslinking structure. The kind of the crosslinking agent may be appropriately selected dependently on the kind of the resin. In a case where EVA is used, an organic peroxide such as benzoyl peroxide, dicumyl peroxide, 2,5-dymethyl-2,5-di(tert-butylperoxy)hexane may be preferably used as the crosslinking agent.

The encapsulant 14c is provided to prevent the solar cells 11 from contacting the output wiring members 16. As mentioned above, since the terminal box 17 is attached at the position from which the output wiring members 16 are drawn, the encapsulant 14c is located near the terminal box 17. In the present embodiment, the second part 16y of each of the output wiring members 16 is disposed just on the rear side of the solar cells 11f and 11g, and the encapsulant 14c is accordingly disposed between the respective second parts 16y and the solar cells 11f and 11g.

The encapsulant 14c is formed of the same material as that of the encapsulant 14a. The terms of “the same material” used herein indicates that the kind and the content of the additives and the like are also the same, in addition to the resin of the main component. In other words, the constituent materials of the respective encapsulants 14a and 14c are the same as each other, in terms of composition of the material and a content ratio of the material, and the physical properties (such as softening temperature and a thermal expansion coefficient) of the encapsulant 14a are the same as those of the encapsulant 14c. The term “same” includes not only a case of being completely identical to each other but also a case of being recognized to be substantially identical. For example, even when slight difference of compositions and the like caused by difference of manufacturing lot may occur, the materials are recognized as substantially identical to each other.

A resin forming the encapsulant 14c (hereinafter, referred to as a “resin 14c”) may be preferably crosslinkable, and has the same crosslinking density as that of the resin 14a and has substantially the same gel fraction as that of the resin 14a. The crosslinking density of the resin 14c may be preferably higher than that of the resin 14b. The encapsulant 14 has a stacked-layer structure of high-crosslinkable resin/(solar cells 11)/high-crosslinkable resin/low-crosslinkable or non-crosslinkable resin in order from the light-receiving surface side at a part where the encapsulant 14c is disposed.

Examples of the suitable combination of the resins 14a, 14b, and 14c may include a case where all of the resins are olefin-based resin or EVA and the crosslinking density of the resins 14a and 14c is higher than that of the resin 14b, and a case where the resins 14a and 14c are crosslinkable EVA and the resin 14b is a non-crosslinkable olefin-based resin.

As mentioned above, the encapsulant 14c is disposed near the terminal box 17. In the present embodiment, the encapsulant 14c is disposed over the range where the output wiring members 16 are disposed and to widely cover the rear surfaces of the solar cells 11f and 11g. The encapsulant 14c is so disposed as to be overlapped with the terminal box 17 in the thickness direction of the solar cell module 10, and to completely cover the surface, of the terminal box 17, facing the light-receiving surface. An area of the encapsulant 14c depends on the size and the like of the solar cell module 10, and may be preferably half or less of the area of each of the encapsulants 14a and 14b, and more preferably one-fifth or less of the area of each of the encapsulants 14a and 14b. The thickness of the encapsulant 14c is not particularly limited, however, and may preferably be about one-quarter to about half of the thickness of each of the encapsulants 14a and 14b.

In the solar cell module 10, the encapsulants 14a and 14c formed of the same material are used on the light-receiving surface side and the rear surface side of the solar cells 11 at a part where the temperature largely differs between in the electric power generation and in the non-electric power generation, namely near the terminal box 17 (directly above the terminal box 17). This makes it possible to reduce shearing stress acting on the solar cells 11f and 11g that are located directly above the terminal box 17. It is conceivable that this is because the physical properties of the encapsulants 14a and 14c are the same as each other, which results in equivalent levels of thermal deformation (thermal expansion and shrinkage) of the encapsulants between on the light-receiving surface side and the rear surface side of the solar cells 11f and 11g. In particular, in a case where the encapsulants 14a and 14c are crosslinkable, creep resistance is improved to improve the effect of the reduction.

The solar cell module 10 having the above-described structure is manufactured by laminating the string of the solar cells 11 to which the wiring materials such as the output wiring members 16 are connected, with use of the first protective member 12, the second protective member 13, and the sheet encapsulants 14a, 14b, and 14c (hereinafter, referred, to as “encapsulant sheets 14a, 14b, 14c”).

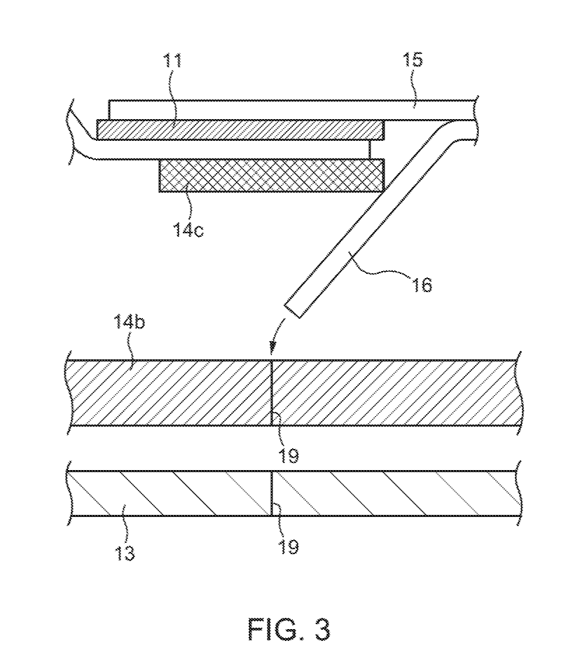

As illustrated in FIG. 3, in the above-described laminating process, the encapsulant sheet 14c is first inserted between each of the solar cells 11 and each of the output wiring members 16 to prevent contact therebetween. The output wiring members 16 are each drawn to the rear side from a slit 19 that is formed in the encapsulant sheet 14b and the second protective member 13. In a laminator, the first protective member 12, the encapsulant sheet 14a, the solar cells 11, the encapsulant sheet 14c, the encapsulant sheet 14b, and the second protective member 13 are stacked in order from the light-receiving surface side on a heater, and the stacked body is heated to about 150° C. in vacuum. Thereafter, heating is continued while the components are pressed against the heater under atmospheric, pressure, to allow the respective resins forming the encapsulant sheets 14a, 14b, and 14c to be crosslinked. Finally, the terminal box 17, the frame 18, and the like are attached to complete the solar cell module 10.

As mentioned above, according to the solar cell module 10, applying the same material as that of the encapsulant 14a to the encapsulant 14c makes it possible to reduce the shearing stress acting on the solar cells 11f and 11g, and accordingly to suppress output deterioration caused by increase in electrode contact resistance, or the like. The solar cell module 10 is largely improved in output characteristics compared with a case where, for example, the same material as that of the encapsulant 14b is applied to the encapsulant 14c.

### REFERENCE SIGNS LIST

10 solar cell module, 11 solar cell, 12 first, protective member, 13 second protective member, 14 encapsulant, 14a first encapsulant, 14b second encapsulant, 14c third encapsulant, 15 conductive wire, 16 output wiring member, 17 terminal box, 18 frame, 19 slit

1. A solar cell module comprising:
a plurality of solar cells;
a first protective member that is provided on a light-receiving surface side of the solar cells;
a second protective member that is provided on a rear surface side of the solar cells;
an output wiring member that passes through the rear surface side of the solar cells and is drawn to the rear surface side of the second protective member;
a terminal box that is provided to the rear surface side of the second protective member and to which the output wiring member is connected;
a first encapsulant that is provided between the solar cells and the first protective member;
a second encapsulant that comprises a different material to that of the first encapsulant and is provided between the solar cells and the second protective member; and
a third encapsulant that comprises the same material as that of the first encapsulant and is provided between the solar cells and the output wiring member.

2. The solar cell module according to claim 1, wherein the first encapsulant and the third encapsulant are formed of a resin having a higher crosslinking density than the crosslinking density of a resin forming the second encapsulant.

3. The solar cell module according to claim 1, wherein the third encapsulant is provided to be overlapped with the terminal box in a thickness direction of the module.
